(19) United States
(12) Patent Application Publication
(10) Pub. No.: US 2026/0314402 A1
(43) Pub. Date: Oct. 8, 2026

(54) ELECTRONIC COMPONENT AND APPARATUS

(71) Applicant: CANON KABUSHIKI KAISHA, Tokyo (JP)

(72) Inventor: TOSHIO TOMIYOSHI, Kanagawa (JP)

(21) Appl. No.: 19/638,652

(22) Filed: Apr. 3, 2026

(30) Foreign Application Priority Data
Apr. 7, 2025 (JP) 2025-063363

(51) Int. Cl. H10W 40/20; H10W 40/28; H10W 70/63

(52) U.S. Cl. CPC H10W 40/235; H10W 40/28; H10W 70/635

(57) ABSTRACT

An electronic component includes: a semiconductor substrate provided with a first surface on which an electronic element is arranged, a second surface on an opposite side to the first surface, an electrode arranged on the second surface, and a through-electrode arranged from the first surface side to the second surface and connected to the electrode; and a Peltier element arranged on the second surface. The electrode arranged on the second surface is arranged outside the Peltier element in a plan view with respect to the second surface.

### BACKGROUND

### Field of the Technology

The present disclosure relates to an electronic component and an apparatus equipped with the electronic component.

### Description of the Related Art

In mounting technology for semiconductor devices, there is a technology that uses an electrode penetrating a semiconductor substrate.

Japanese Patent Application Laid-Open No. 2018-85353 discloses a module in which a circuit of a semiconductor element and a circuit of a substrate are connected via a via penetrating the semiconductor element.

### SUMMARY

The present disclosure provides an electronic component having a structure advantageous for suppressing heat generation of a semiconductor substrate provided with a through-electrode.

According to one aspect of the present disclosure, there is provided an electronic component including: a semiconductor substrate provided with a first surface on which an electronic element is arranged, a second surface on an opposite side to the first surface, an electrode arranged on the second surface, and a through-electrode arranged from the first surface side to the second surface and connected to the electrode; and a Peltier element arranged on the second surface, wherein the electrode arranged on the second surface is arranged outside the Peltier element in a plan view with respect to the second surface.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1A is a diagram schematically showing a first surface of an electronic component according to a first embodiment.

FIG. 1B is a diagram schematically showing a second surface of the electronic component according to the first embodiment.

FIG. 2 is a diagram schematically showing a cross-section of an electronic component according to the first embodiment.

FIG. 3 is a diagram schematically showing a cross-section of an electronic component according to the first embodiment.

FIG. 4 is a diagram schematically showing a cross-section of the electronic component according to the first embodiment.

FIG. 5 is a diagram schematically showing a cross-section of an electronic component according to the first embodiment.

FIG. 6 is a diagram schematically showing a cross-section of an electronic component according to the first embodiment.

FIG. 7 is a diagram schematically showing a cross-section of an electronic component according to a second embodiment.

FIG. 8 is a perspective view schematically showing an example of an electronic component according to the second embodiment.

FIG. 9 is a diagram schematically showing an application example of an electronic component to an apparatus.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In the following description, terms indicating specific directions or positions (for example, "top", "bottom", "right", "left", and other terms including those terms) are used as necessary. The use of those terms is to facilitate the understanding of the embodiments with reference to the drawings, and the technical scope of the present disclosure is not limited by the meaning of those terms.

A semiconductor substrate on which a semiconductor element is mounted has a first surface and a second surface on the opposite side to the first surface. For example, when a side where an electronic element is arranged is defined as a main surface, the main surface can be called a first surface. In that case, the opposite side to the first surface can be called a second surface. Further, the second surface can also be called a back surface with respect to the main surface.

### First Embodiment

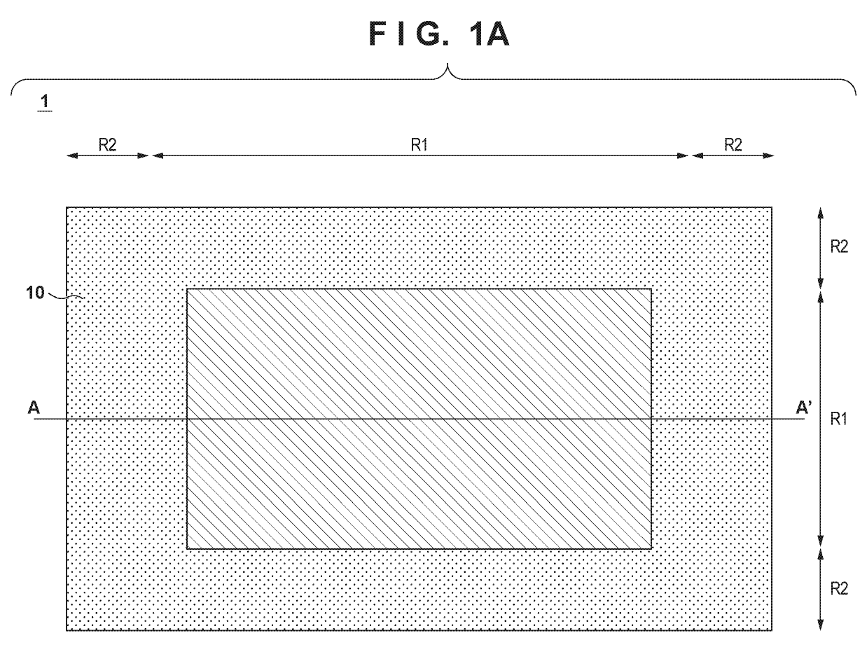

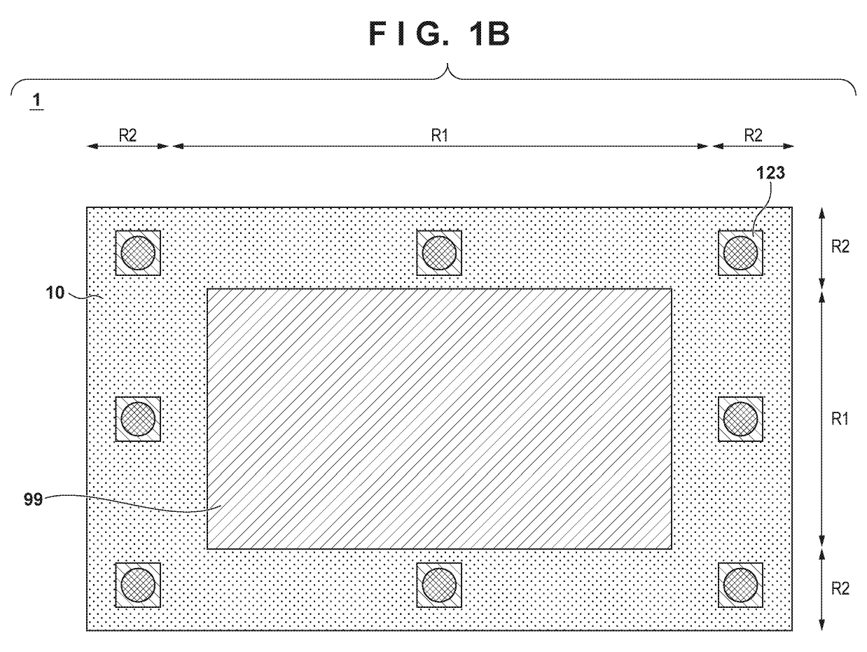

An electronic component 1 according to the present embodiment will be described with reference to FIGS. 1A, 1B and 2. FIGS. 1A and 1B show plan views when the electronic component 1 is viewed in a plan view. To view in a plan view means to view the electronic component from a direction perpendicular to the main surface of the electronic component 1 (a normal direction of the main surface). FIG. 1A is a plan view viewed from the first surface, and FIG. 1B is a plan view viewed from the second surface on the opposite side to the first surface. Further, FIG. 2 shows a cross-sectional view along line A-A' in FIG. 1A. Hereinafter, the same members are denoted by common reference numerals, and description will be given while referring to each drawing mutually.

The electronic component 1 includes a semiconductor device 10 and a cooling member 99. A Peltier element can be used for the cooling member 99. As shown in FIGS. 1A and 1B, the semiconductor device 10 includes a region R1 in which an element having a main function of the semiconductor device 10 is arranged, and a region R2 on the outer periphery of the region R1. The cooling member 99 is arranged on the second surface of the semiconductor device 10. A backside electrode 123 is formed on the outside of the cooling member 99. The backside electrode 123 is an electrode connected to a wiring substrate, and can be called a backside electrode 123.

The electronic component 1 will be described with reference to FIG. 2. The semiconductor device 10 includes a semiconductor substrate 101 such as a single crystal silicon substrate. Electronic elements are arranged on a first surface S1 of the semiconductor substrate 101. In FIG. 2, a semiconductor element 102 is shown as an example of an electronic element. An example of the semiconductor element 102 is a MOS transistor. In the example of a MOS transistor, the semiconductor element 102 has a structure including a source, a drain, and a gate.

The semiconductor element 102 is not limited to a MOS transistor, and can include various structures depending on functions required for the semiconductor device. For example, the semiconductor element may include a photoelectric conversion element such as a photodiode, a capacitive element, or a Single Photon Avalanche Diode (SPAD), or the like. Furthermore, the semiconductor element may include a Light Emitting Diode (LED) element which is a light emitting element or an organic Electro Luminescence (EL) element. Further, an amplification circuit, a processing circuit, and a control circuit can be configured by such semiconductor elements 102.

In the following description, the semiconductor element 102 shall be provided with a function as an optical sensor, but the semiconductor element is not limited to an optical sensor. Here, the optical sensor will be described as being provided with a photoelectric conversion unit including a photoelectric conversion element, or a photoelectric conversion unit (pixel portion) and a circuit (peripheral circuit portion) for processing a signal generated therefrom, or the like.

In FIG. 2, the semiconductor element 102 is arranged on the first surface S1 side of the semiconductor substrate 101, and a wiring layer 106 is provided on the second surface S2 side opposite to the first surface S1. A portion where the semiconductor element 102 and the wiring layer 106 are arranged is called a functional layer 201. The wiring layer 106 is a layer having an insulating film and a plurality of wiring layers arranged in the insulating film. Note that, although a multilayer wiring structure of four layers is shown as an example of the wiring layer 106 in FIG. 2, the number of layers of the wiring layer is not limited to four layers.

In the wiring layer 106, semiconductor elements 102 are electrically connected to each other via contact plugs and wirings so as to configure a desired circuit or structure. A part of the wirings configuring the wiring layer 106 is connected to a pad electrode 107. The pad electrode 107 may constitute a part of the wiring layers constitute the wiring layer 106. A plurality of pad electrodes 107 can be arranged, for example, in a peripheral portion of the semiconductor device 10.

Here, an example is shown in which, when some of the semiconductor elements 102 are pixels having a function of a photoelectric conversion unit, a region where pixels having a main function are arranged is defined as a region R1. A peripheral circuit region for processing signals can be arranged in the periphery outside the region R1. With respect to the region R1, a region where other peripheral circuits can be arranged is defined as a region R2. The region R2 can be a region in the vicinity surrounding the region R1. The size and location of the region R2 do not matter.

Further, a part of the semiconductor substrate 101 on the second surface S2 side is a support substrate 109. The support substrate 109 is a semiconductor such as a single crystal silicon substrate, for example. A through-electrode 122 for connecting to the pad electrode 107 can be arranged in the support substrate 109. The through-electrode 122 is called, for example, a Through Silicon Via (TSV). Further, a portion of the support substrate 109 where the through-electrode 122 is arranged can be called a support layer 202 in the semiconductor device 10. The through-electrode 122 is connected to the backside electrode 123, which is an electrode for extracting signals or the like. The wiring layer 106 on the first surface S1 side and the backside electrode 123 are electrically connected by the through-electrode 122. The backside electrode 123 is a conductive metal including Au, Al, Cu, Sn, Ag, or the like, and may be an alloy. Further, the shape of the backside electrode 123 may be only an electrode pad, or a hemispherical or columnar bump. Further, a stacking structure may be taken in which the functional layer 201 and the support layer 202 are formed on separate semiconductor substrates and joined using a joining material made of an insulating material such as silicon oxide and a metal material such as Al, Ti, W, or copper.

As shown in FIG. 2, a cooling member 99 is joined so as to contact the surface of the semiconductor device 10 on the backside electrode 123 side. A plurality of backside electrodes 123 can be arranged outside the region where the cooling member 99 is arranged.

An adhesive, a conductive paste, or the like can be used for joining the cooling member 99 and the semiconductor device 10. A joining material with high thermal conductivity such as silver paste may be used. As the cooling member 99, a thermoelectric element such as a Seebeck element can be used in addition to a Peltier element. Note that the joining material and the joining method are not limited to the present embodiment.

In the case of a structure in which a wiring substrate and a semiconductor substrate are connected via a through-electrode penetrating the semiconductor substrate, heat generation may not be sufficiently suppressed. The cooling member 99 can be installed so as to cover a part of the region R1 or the entire region R1. When pixels are arranged in the region R1, a large number of semiconductor elements 102 are formed in the region R1 and high-density wiring may concentrate, so that current density can become high. As the current density becomes high, the amount of heat generation increases. By installing the cooling member 99 at a position corresponding to the region R1, it is possible to efficiently cool the portion that generates heat.

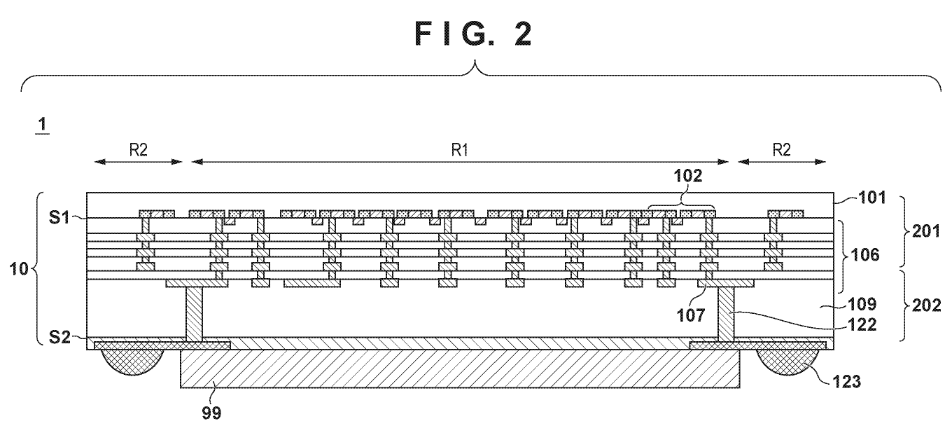

FIG. 3 is an example of an electronic component 2 in which the semiconductor device 10 and the cooling member 99 are mounted on a wiring substrate 301. A wiring electrode 302 open to the outside is formed on the wiring substrate 301, and the wiring substrate 301 is connected to the semiconductor device 10 via the backside electrode 123. Further, a current for driving the cooling member can be supplied from the wiring substrate 301 to the cooling member 99 via a wiring 303. As the wiring substrate 301, a glass epoxy board, a liquid crystal polymer board, a ceramic board, or the like can be used. It is desirable that the wiring substrate 301 has little deformation and low thermal conductivity.

The wiring substrate 301 may have, for example, a shape in which a part is cut away, and may have a shape that does not contact the cooling member 99. The wiring substrate 301 may have a frame-shaped opening 310 that surrounds the cooling member 99. By providing the opening 310 as shown in FIG. 3, the cooling member can dissipate heat through the opening 310. If a gap is provided between the cooling member 99 and the wiring substrate 301 at the cutout portion or the frame-shaped opening 310 of the wiring substrate 301, exhaust heat from the cooling member 99 is not transmitted to the wiring substrate 301. Since heat re-entry into the semiconductor device 10 can be suppressed, it is advantageous for cooling, and it becomes possible to efficiently cool only the heat generating portion.

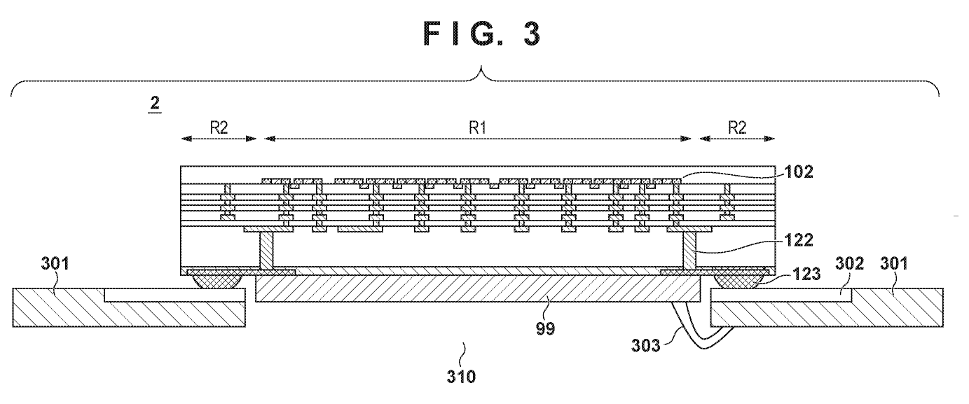

FIG. 4 shows an example of an electronic component 3 in which the semiconductor device 10 is connected to the wiring substrate 301 via an interposer 801. In this example, the interposer 801 is arranged between the backside electrode 123 and the wiring substrate 301. Also in the case of this example, the wiring substrate 301 may be provided with a portion cut away according to the shape of the cooling member 99 or a frame-shaped opening 310. In FIG. 4, the opening 310 is provided at a position corresponding to the cooling member 99.

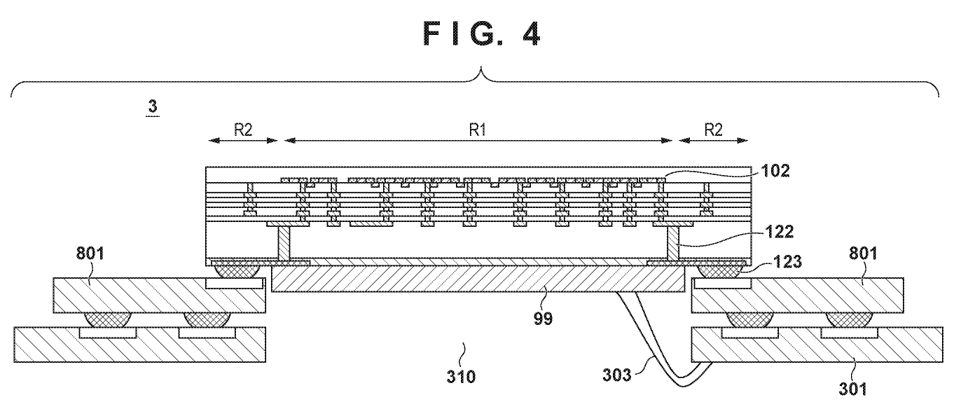

Next, an example of an electronic component 4 in which a photoelectric conversion element or a light emitting element is arranged in a semiconductor device and an optical structure is further arranged will be described with reference to FIG. 5. On an upper surface S3 where the semiconductor element 102 is arranged on the side opposite to the side where the cooling member 99 is arranged, a planarization layer 113, a color filter layer 114, and a microlens 116 are arranged in order from the surface S3 as an optical structure. On the microlens 116, a joining resin layer 203 including a filling resin 124 having translucency and an outer peripheral seal resin 125 is arranged.

A cover glass 121 having translucency is joined on the joining resin layer 203. A hollow structure without the filling resin 124 may be used between the microlens 116 and the cover glass 121. The optical structure described here is an example and there is no limitation to these configurations. When the semiconductor device 20 is a device having a large number of pixels in the region R1 such as an optical sensor or a display, the cooling member 99 is disposed so as to overlap a part of or the entire region R1. Heat generated from the region R1 including pixels can be suppressed from the back surface of the semiconductor device 20 by the effect of the cooling member 99.

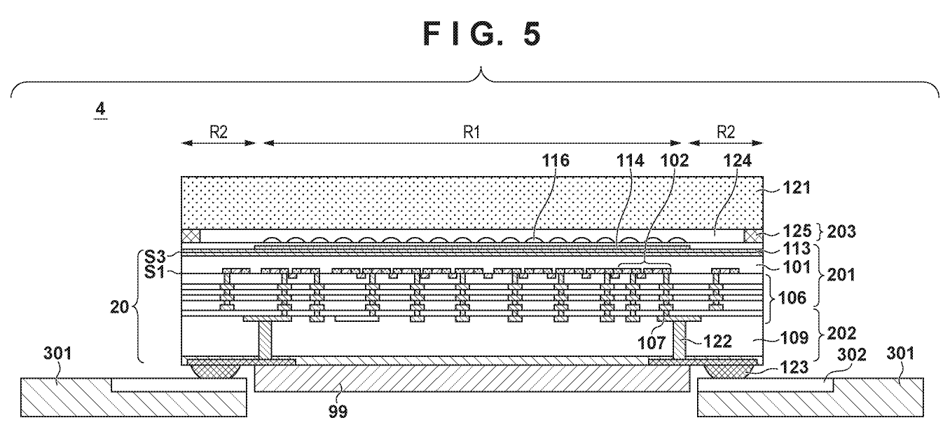

An example in which functional elements are arranged in a plurality of layers will be described below with reference to FIG. 6. FIG. 6 shows a cross-sectional view of an electronic component 5. X-Y shown in FIG. 6 indicate directions for the cross-section. Here, description will be given by an example in which the semiconductor element 102 is formed in the electronic component 5. The electronic component 5 is an example having a structure in which a plurality of a semiconductor device 12, a semiconductor device 13, and a semiconductor device 14 into which the semiconductor element 102 is incorporated are stacked. The semiconductor device 12 to the semiconductor device 14 may have different functions for each layer. For example, each layer may include an optical sensor element, an A/D conversion element, a memory element, a logic element, or the like, respectively. The electronic component 5 includes an interface substrate 15 including a silicon substrate and having wirings formed therein, between the semiconductor device 14 and the wiring substrate 301. A semiconductor device 30 includes a structure in which from the semiconductor device 12 to the interface substrate 15 are stacked.

The semiconductor devices of each layer can be arbitrarily combined to obtain desired functions and characteristics. Although this example is configured with three layers of the semiconductor devices 12 to 14 and the interface substrate 15, the number of these layers is not limited to this example. Further, the interface substrate 15 may not be used. Electrical connections 126 can be made between semiconductor layers included in the semiconductor devices. As a connection method, Cu-Cu bonding, Au-Au bonding, bonding by various bumps, or the like can be used.

Through-electrodes and contact plugs are formed inside the semiconductor device 12 to the semiconductor device 14, and connections within semiconductor layers and between semiconductor layers can be made. The cooling member 99 is joined to one surface of the semiconductor device 30. Furthermore, the backside electrode 123 of the interface substrate 15 and the wiring electrode 302 of the wiring substrate 301 can be electrically connected.

In the semiconductor devices configuring the respective layers of the electronic component 5, for example, a plurality of pixels having photoelectric conversion elements can be provided in the semiconductor device 12, and peripheral circuits can be arranged in the semiconductor device 13 and the semiconductor device 14. In the electronic component 5, heat is generated from each of the stacked semiconductor layers. Since the through-electrode 122 made of a metal material extends in the Y direction of FIG. 6, thermal conduction tends to be high in the Y direction. The thermal distribution of the electronic component 5 has a characteristic that a high-temperature region concentrates in the center of the element, and heat is easily transmitted in the Y direction. The cooling member 99 is arranged so as to cover the central portion of the back surface of the electronic component 5. Efficient cooling becomes possible by this arrangement. Further, by providing a gap between the wiring substrate 301 and the cooling member 99 to structurally separate them, heat is not directly transmitted to the wiring substrate 301, so that heat re-entry into the semiconductor device 30 can be reduced. Therefore, efficient cooling of the heat generating portion becomes possible.

### Second Embodiment

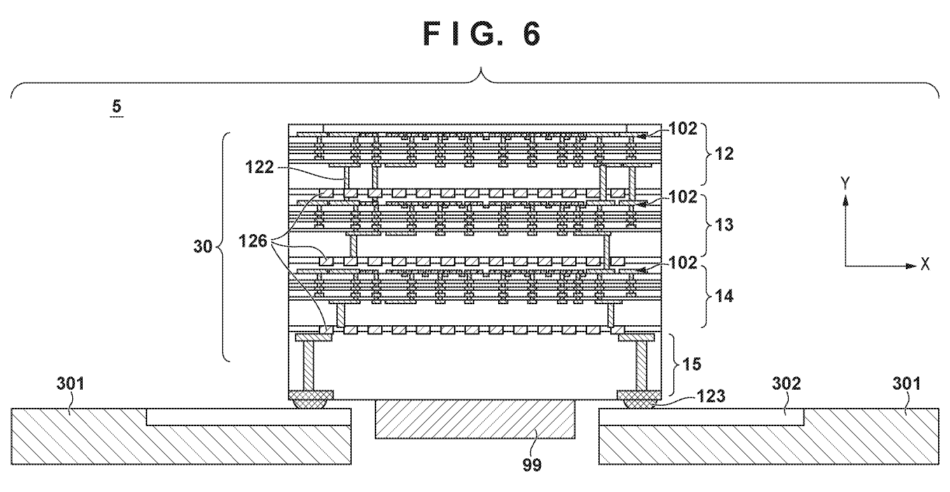

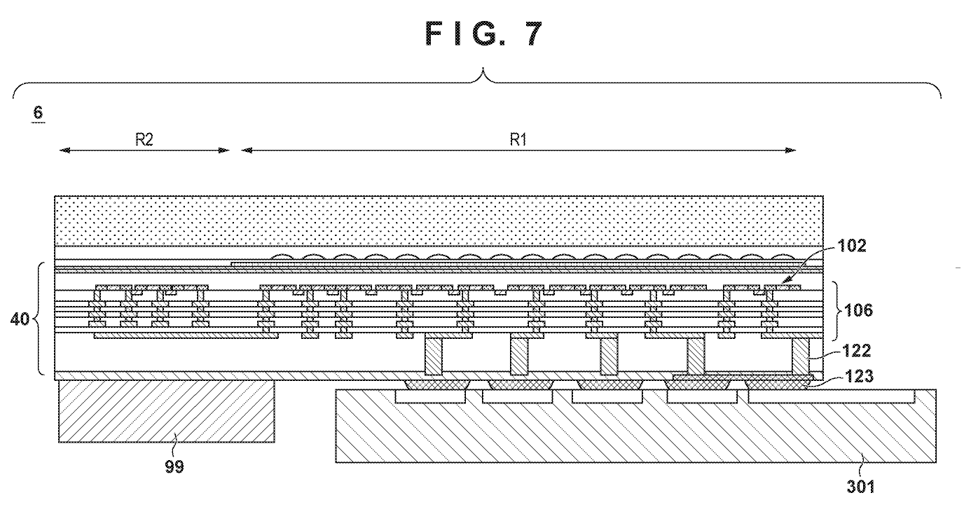

Present embodiment will be described with reference to FIGS. 7 and 8. Description of configurations common to the first embodiment will be omitted. FIG. 7 schematically shows a cross-section of a configuration of an electronic component 6 of the present embodiment, and FIG. 8 schematically shows a perspective view of the electronic component 6 of the present embodiment. FIG. 7 shows a cross-section along line B-B' in FIG. 8.

Description will be given by an example in which a semiconductor element 102 is formed similarly to the first embodiment. The electronic component 6 includes a semiconductor device 40 and a cooling member 99. The semiconductor device 40 can have a region R1 including pixels in which some of the semiconductor elements 102 have a function of a photoelectric conversion unit, and a region R2 including other peripheral circuits. On a second surface on the opposite side to a first surface when the side where light is incident on the semiconductor device 40 is defined as the first surface, a cooling member 99 is joined so as to cover a part or all of the region R2 in a plan view. The semiconductor device 40 is joined to a wiring substrate 301 at the portion of the region R1.

FIG. 8 is a perspective view showing a positional relationship between the region R1 and the region R2. Electrical connection to the wiring substrate 301 can be made via a wiring layer 106 or a backside electrode 123 in the region R1. Peripheral circuits in the region R2 include an A/D conversion circuit, a circuit for driving pixels, and the like. Since the A/D conversion circuit and the driving circuit can have large power consumption, heat generation may become larger than that of the region R1 in which the pixels are arranged. In the electronic component 6, by joining the cooling member 99 so as to overlap the region R2 in a plan view as shown in FIGS. 7 and 8, it becomes possible to directly cool the vicinity of a heat generating portion. By cooling the circuit in the region R2, it is possible to suppress heat generated from the region R2 from affecting the pixels in the region R1, so that noise generated by the photoelectric conversion element and degradation of the element can be suppressed.

In the example shown in FIG. 8, the region R2 including the peripheral circuit is provided in a part of the semiconductor device 30, but there may be two or more regions R2 including the peripheral circuit. Similarly, two or more cooling members 99 may be arranged corresponding to positions that generate heat.

### Application Example of Electronic Component to Apparatus

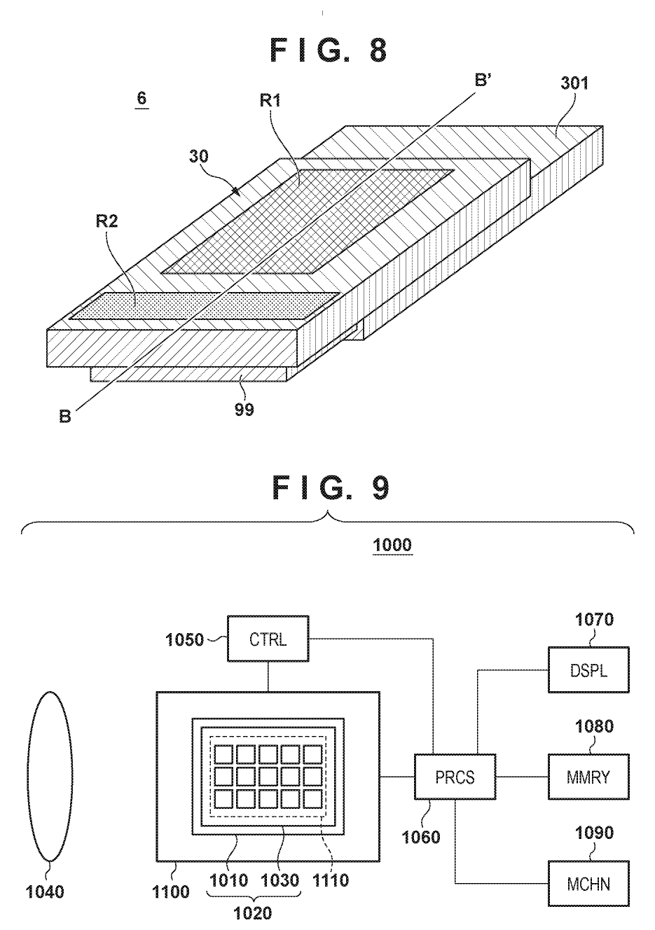

An example in which the electronic component according to the above-described embodiment is applied to an apparatus 1000 will be described with reference to FIG. 9. An electronic component 1100 including a package 1020 on which a semiconductor chip 1110 is placed is mounted on the apparatus 1000. The electronic component 1100 is an electronic component according to an above-described embodiment in which a cooling member (not shown) is arranged between a base 1010 of the package 1020 and the semiconductor chip 1110. The electronic component 1100 can include a package 1020 including a base 1010 to which the semiconductor chip 1110 is fixed, and a light-transmitting member 1030 such as glass facing the semiconductor chip 1110. In the package 1020, joining members such as wires or bumps connecting inner leads provided on the base 1010 and terminals such as pad electrodes provided on the semiconductor chip 1110 can be arranged.

The apparatus 1000 can include at least any one of an optical device 1040, a control device 1050, a processing device 1060, a display device 1070, a storage device 1080, and a mechanical device 1090. The optical device 1040 is, for example, a lens, a shutter, or a mirror. The control device 1050 controls the semiconductor chip 1110. The control device 1050 is, for example, a semiconductor device such as an ASIC.

The processing device 1060 processes an output signal from a semiconductor integrated circuit included in the semiconductor chip 1110. The processing device 1060 is a semiconductor device such as a CPU or an ASIC for configuring an AFE (analog front end) or a DFE (digital front end). For example, at the time of event detection, an image may be generated based on an imaging signal. The display device 1070 is an EL display device or a liquid crystal display device that displays an information image obtained by the semiconductor chip 1110. The storage device 1080 is a magnetic device or a semiconductor device that stores an information image obtained by the semiconductor chip 1110. The storage device 1080 is a volatile memory such as an SRAM or a DRAM, or a non-volatile memory such as a flash memory or a hard disk drive.

The mechanical device 1090 has a movable portion or a propulsion portion such as a motor or an engine. In the apparatus 1000, a signal output from the semiconductor chip 1110 is displayed on the display device 1070 or transmitted to the outside by a communication device (not shown) provided in the apparatus 1000. For that purpose, the apparatus 1000 may further include the storage device 1080 and the processing device 1060 separately from a storage circuit and an arithmetic circuit included in the semiconductor chip 1110. The mechanical device 1090 may be controlled based on a signal output from the semiconductor chip 1110.

The apparatus 1000 is suitable for an electronic apparatus such as an information terminal having a photographing function, for example, a smartphone, a wearable terminal, or a camera, for example, an interchangeable lens camera, a compact camera, a video camera, or a surveillance camera. The mechanical device 1090 in the camera may be a device that can drive parts of the optical device 1040 for zooming, focusing, and shutter operation. Alternatively, the mechanical device 1090 in the camera may be a device that can move the optical device 1040 for an anti-vibration operation.

Further, the apparatus 1000 can be transportation equipment such as a vehicle or a ship. The mechanical device 1090 in the transportation equipment can be used as a moving device. The apparatus 1000 as transportation equipment is suitable for one that transports the semiconductor chip 1110, or one that performs assistance and/or automation of a driving operation by a photographing function. The processing device 1060 for assistance and/or automation of a driving operation can perform processing for operating the mechanical device 1090 as a moving device based on information obtained by the semiconductor chip 1110. Alternatively, the apparatus 1000 may be a medical device such as an endoscope, a measurement device such as a distance measuring sensor, an analysis device such as an electron microscope, an office device such as a copying machine, or an industrial device such as a robot.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2025-063363, filed Apr. 7, 2025 which is hereby incorporated by reference herein in its entirety.

What is claimed is:

1. An electronic component comprising: a semiconductor substrate having a first surface on which an electronic element is arranged, a second surface on an opposite side to the first surface, an electrode arranged on the second surface, and a through-electrode arranged from the first surface side to the second surface and connected to the electrode; and a Peltier element arranged on the second surface,
wherein the electrode arranged on the second surface is arranged outside the Peltier element in a plan view with respect to the second surface.

2. The electronic component according to claim 1, wherein the Peltier element covers a part of the second surface.

3. The electronic component according to claim 1, wherein the electronic element includes a photoelectric conversion element.

4. The electronic component according to claim 3, wherein the Peltier element covers a part or all of a region in which the photoelectric conversion element is arranged in the plan view.

5. The electronic component according to claim 1, wherein the electronic element is a light emitting element.

6. The electronic component according to claim 5, wherein the Peltier element covers a part or all of a region in which the light emitting element is arranged in the plan view.

7. The electronic component according to claim 1, wherein a light-transmitting member is arranged on the first surface.

8. The electronic component according to claim 1, wherein the Peltier element is joined to the second surface via a member having high thermal conductivity.

9. The electronic component according to claim 1, wherein two or more Peltier elements are arranged.

10. The electronic component according to claim 1, further comprising a wiring substrate, wherein the electrode arranged on the second surface is connected to the wiring substrate.

11. The electronic component according to claim 10, wherein an electrode for connecting a wiring that supplies a current to the Peltier element is arranged on the wiring substrate.

12. The electronic component according to claim 10, wherein the wiring substrate has a frame-shaped opening in a plan view, and the Peltier element is arranged in the opening.

13. The electronic component according to claim 12, wherein there is a gap between the Peltier element and the frame-shaped opening.

14. The electronic component according to claim 10, further comprising an interposer, wherein the electrode arranged on the second surface is connected to the wiring substrate via the interposer.

15. An apparatus comprising: the electronic component according to claim 1; and a processing device that controls the electronic component.
